(19) United States
(12) Patent Application Publication
(10) Pub. No.: US 2002/0110967 A1
(43) Pub. Date: Aug. 15, 2002

(54) Method of forming metal lines in an integrated circuit using hard mask spacers

(76) Inventor: Jing-Xian Huang, Hsin-Chu (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/785,933

(22) Filed: Feb. 15, 2001

(51) Int. Cl. H01L 21/336; H01L 21/8234

(52) U.S. Cl. 438/197

(57) ABSTRACT

A method of forming metal lines is disclosed. The method comprises forming a metal layer over a semiconductor substrate. A hard mask layer is then formed over the metal layer. The hard mask layer is then patterned and etched with a pattern corresponding to the desired metal line pattern. Sidewall spacers are then formed on the sidewalls of the hard mask layer. Finally, the metal layer is etched using the hard mask layer and sidewall spacers as a mask.

### TECHNICAL FIELD OF THE INVENTION

The present invention relates to fabricating a metal line in an integrated circuit, and more particularly, to a method of fabricating a wider metal line using existing photolithography techniques to reduce sheet resistance.

### BACKGROUND OF THE INVENTION

In semiconductor integrated circuit (IC) fabrication, metal lines are deposited to interconnect IC components and to connect IC components to pads. The metal lines are formed by physical deposition (such as by sputtering) of a layer of metal (such as aluminum or an aluminum-copper alloy). Photoresist is applied to the metal layer to define a pattern for forming lines that interconnect the desired components of the IC.

As the line widths continue to decrease, the sheet resistance of the metal lines will become larger. Thus, what is needed is a method for reducing sheet resistance of metal lines.

### BRIEF DESCRIPTION OF THE DRAWINGS

FIGS. 1-4 are cross sectional views of a semiconductor substrate illustrating the formation of a metal line in accordance with the present invention.

### DESCRIPTION OF THE PREFERRED EMBODIMENT

In the following description, numerous specific details are given to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

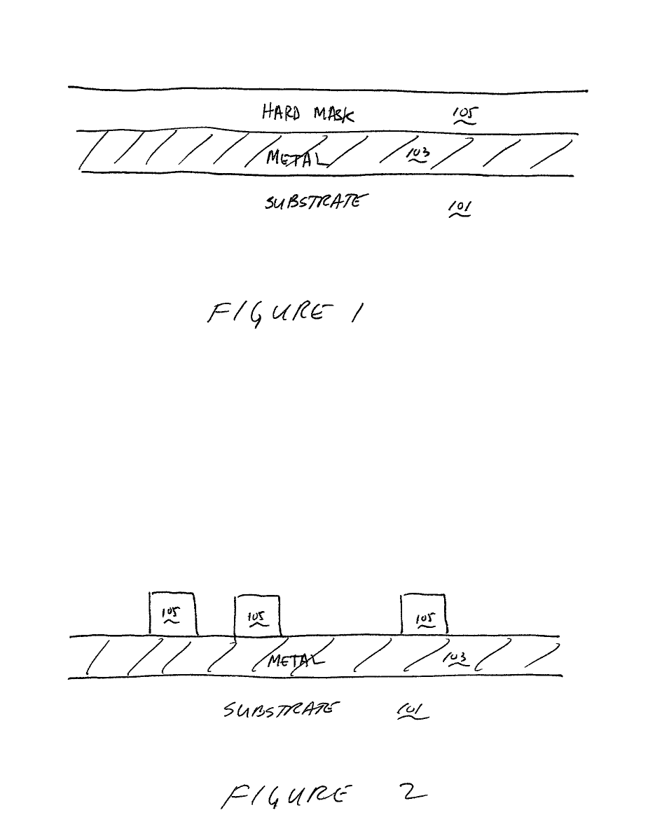

Turning to FIG. 1, a semiconductor substrate 101 is shown. The term “semiconductor substrate” as used herein may mean a semiconductor wafer, a dielectric layer (such as an interlayer dielectric or intermetal dielectric), or any type of underlying layer found in the fabrication of integrated circuits. Typically, the substrate 101 is either an interlayer or intermetal dielectric formed from some form of silicon dioxide, i.e., TEOS, BPSG, SOG, etc . . .

Formed atop of the substrate 101 is a metal layer 103. The metal layer may be aluminum, copper, or any combination of conductive materials. For example, the metal layer 103 may be a metal stack that includes a titanium/titanium nitride layer formed on the substrate. Typically, the titanium/titanium nitride layer is formed by depositing a titanium layer to a thickness of about 100 angstroms. This is followed by a layer of titanium nitride to a thickness of less than 500 angstroms. Further, the metal stack may include a conductive layer, such as aluminum, copper, or an aluminum-copper alloy. Finally, formed atop of the conductive layer may be a top titanium/titanium nitride layer. The foregoing is one example of a metal stack that forms the metal layer 103.

Next, formed atop of the metal layer is a hard mask layer 105. The hard mask layer 105 may be a dielectric layer, such as silicon nitride, silicon oxide, oxynitride, or any combination of these dielectrics. In one embodiment, the hard mask layer 105 is between 1500 and 3000 angstroms thick. The hard mask layer 105 should be formed from a material that can be used as an etching mask when etching the metal layer 103. For example, the hard mask layer 105 may be silicon nitride (Si₃N₄).

Next, turning to FIG. 2, the hard mask layer 105 is patterned and etched using photolithography techniques. The etching of the hard mask is performed using an anisotropic etch using CHF₃ flowing at 30-100 sccm, CF₄ flowing at 15-50 sccm, at a pressure of between 100-250 millitorr. The hard mask layer 105 is etched so that the remaining portions of the hard mask layer 105 substantially conform to the desired metal line pattern.

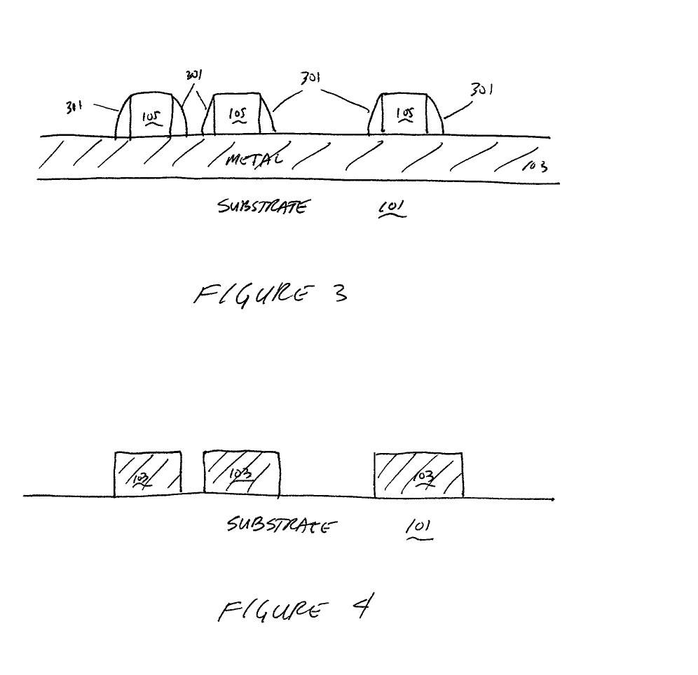

Next, turning to FIG. 3, sidewall spacers 301 are formed on the sidewalls of the remaining portions of the hard mask layer 105. The formation of sidewall spacers may be accomplished by the deposition of a thin film of dielectric material, such as an oxide or nitride or oxynitride. Next, the thin film of dielectric material is etched back to form sidewall spacers. The etching of the dielectric material is performed using an anisotropic etch using CHF₃ flowing at 30-100 sccm, CF₄ flowing at 15-50 sccm, at a pressure of between 100-250 millitorr. The resulting formation is shown in FIG. 3.

Finally, using the hard mask layer 105 and the sidewall spacers 301 as a mask, the metal layer 103 is etched using a metal etch. The result is seen in FIG. 4, which shows the metal layer 103 being etched into a desired pattern of metal lines. Further, the spacing between adjacent metal lines is reduced and the width of the metal lines is increased. This allows reduced sheet resistance in the metal line. Additionally, by using this process, the “wide” metal lines may be placed closer to each other than could be achieved using conventional photolithography techniques.

Although specific embodiments including the preferred embodiment have been illustrated and described, it will be obvious to those skilled in the art that various modifications may be made without departing from the spirit and scope of the present invention, which is intended to be limited solely by the appended claims.

What is claimed is:

1. A method of forming metal lines comprising:
forming a metal layer over a semiconductor substrate;
forming a hard mask layer over said metal layer;
patterning and etching said hard mask layer with a pattern corresponding to said metal lines;
forming sidewall spacers on said hard mask layer; and
etching said metal layer using said hard mask layer and said sidewall spacers as a mask.

2. The method of claim 1 wherein said hard mask is formed from silicon nitride, silicon oxide, oxynitride, or any combination thereof.

3. The method of claim 1 wherein said sidewall spacers are formed from silicon nitride, silicon oxide, oxynitride, or any combination thereof.

4. The method of claim 1 wherein said hard mask layer and said sidewall spacers are formed from oxide, silicon oxide, oxynitride, or any combination thereof.

5. The method of claim 1 wherein the width of said metal lines is larger than the spacing between said metal lines.

6. The method of claim 1 wherein the etching of said hard mask layer is performed using CHF₃ flowing at 30-100 sccm, CF₄ flowing at 15-50 sccm, and at a pressure of between 100-250 millitorr.

7. The method of claim 1 wherein the sidewall spacers are formed by etching a dieletric material using CHF₃ flowing at 30-100 sccm, CF₄ flowing at 15-50 sccm, and at a pressure of between 100-250 millitorr.

8. The method of claim 1 wherein said hard mask layer is between 1500 and 3000 angstroms thick.
